(19) United States
(12) Patent Application Publication
(10) Pub. No.: US 2008/0157255 A1
(43) Pub. Date: Jul. 3, 2008

(54) SEMICONDUCTOR RADIATION DETECTOR AND RADIATION DETECTION EQUIPMENT

(76) Inventors: Shinya Kominami, Mito (JP); Tomoyuki Seino, Hitachi (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/836,411

(22) Filed: Aug. 9, 2007

(30) Foreign Application Priority Data
Sep. 29, 2006 (JP) 2006-268570

(51) Int. Cl. H01L 27/146

(52) U.S. Cl. 257/459; 257/E27.13

(57) ABSTRACT

A semiconductor radiation detector and a radiation detection equipment capable of suitably preventing the deterioration of the detection characteristics are disclosed. The semiconductor radiation detector 1 includes a semiconductor crystal 11a formed of at least one of CdTe, CdZnTe, GaAs and TlBr held between the electrodes of a cathode C and an anode A. At least one of the electrodes is a stack structure including a plurality of metals. The first layer is formed of Pt or Au, and the second layer is formed of a metal lower in hardness than Pt or Au, as the case may be, of the first layer. The second layer of In, for example, is formed by the electroless plating method. Also, a metal may be further stacked on the second layer.

### BACKGROUND OF THE INVENTION

This invention relates to a semiconductor radiation detector and a radiation detection equipment.

In recent years, the nuclear medicine diagnosis device has been widely used as a radiation detection equipment using the radiation measurement technique. Typical equipment include a positron emission tomography equipment (PET equipment), a single photon emission computed tomography equipment (SPECT equipment) and a gamma-camera equipment. The radiation detector mainly used in these equipments is a combination of a scintillator and a photomultiplier. A technique using the semiconductor radiation detector configured of the semiconductor crystal such as CdTe (cadmium telluride), CdZnTe (cadmium-zinc-tellurium), GaAs (gallium arsenide) or TlBr (thallium bromide) is closely watched as a radiation detector for detecting the radiation such as γ ray. The semiconductor radiation detector is configured to convert the charge generated by interaction between the radiation and the semiconductor crystal into an electrical signal, and therefore, higher in conversion efficiency into an electrical signal than using the scintillator. At the same time, the semiconductor radiation detector can be made compact and has various other features.

The semiconductor radiation detector includes the semiconductor crystal described above and electrodes formed on the two surfaces of the semiconductor crystal. A DC high voltage is applied between the electrodes so that the charge generated by the radiation such as X ray or γ ray incident to the semiconductor crystal is retrieved as a signal from the electrodes.

The electrodes can be formed by the vacuum evaporation method or the electroless plating method (See, for example, JP-A-3-248578).

In the assembly process for the semiconductor radiation detector, an electrode plate is electrically bonded through an electroconductive adhesive to each side of the anode electrode and the cathode electrode formed on the semiconductor crystal. In order to secure a high conductivity due to the electroconductive adhesive in bonding the electrode plates, a stacked electrode plate is pressed under a predetermined pressure from each side while at the same time drying by heating at a predetermined temperature.

The compound such as CdTe used as a semiconductor crystal is known to be a soft, fragile material. In the case where the electrode plate is bonded under pressure as described above in the process of assembling the semiconductor radiation detector, a crystal dislocation is liable to occur disadvantageously in the semiconductor crystal.

The occurrence of the crystal dislocation in the semiconductor crystal poses the problem that the dark current of the semiconductor radiation detector increases and the detection characteristic of the semiconductor radiation detector is deteriorated.

### SUMMARY OF THE INVENTION

Accordingly, it is an object of this invention to solve this problem and provide a semiconductor radiation detector and a radiation detection equipment capable of suitably preventing the deterioration of the detection characteristic.

In order to solve the problem described above, according to this invention, there is provided a semiconductor radiation detector and a radiation detection equipment, wherein at least one of the cathode electrode and the anode electrode includes a plurality of metals stacked in layers with the first layer being formed of Pt or Au and the second layer of a metal such as In lower in hardness than the metal of the first layer. With this configuration, in the assembly process of the semiconductor radiation detector, In of the second layer functions as a buffer material against the first layer of Pt or Au harder than In, and the pressure of bonding the electrode plate through the electroconductive adhesive is suitably alleviated. As a result, the semiconductor crystal develops no crystal dislocation and the deterioration of the detection characteristic of the semiconductor radiation detector is suitably prevented.

Also, in the case where the element In contained in the second layer is formed by electroless plating method, the semiconductor crystal is not exposed to a high temperature in forming the second layer. Thus, the second electrode of the semiconductor crystal, if formed in a previous process, is not deteriorated by heat. As a result, the deterioration of the detection characteristic is suitably prevented.

Further, in the case where any one of In, Ti or Al is used as the second electrode, and a layer is a combination of two or more layers including the first layer which is any one of In, Ti or Al, in the second electrode, the second electrode of the semiconductor crystal can suitably exhibit the function thereof. Especially in the case where the first layer is formed of In, the second electrode can have the function of both an electrode and a buffer material for alleviating the pressure of bonding the electrode plate. In this way, the deterioration of the detection characteristic is suitably prevented.

Also, in the radiation detection equipment having the aforementioned semiconductor radiation detector, the deterioration of the detection characteristic of the semiconductor radiation detector is suitably prevented, with the result that the energy resolution and the positional resolution can be improved in accuracy.

According to this invention, a semiconductor radiation detector and a radiation detection equipment capable of suitably preventing the deterioration of the detection characteristic are provided.

Other objects, features and advantages of the invention will become apparent from the following description of the embodiments of the invention taken in conjunction with the accompanying drawings.

### BRIEF DESCRIPTION OF THE DRAWINGS

FIG. 1A is a perspective view schematically showing the semiconductor radiation detector according to a first embodiment of the invention.

FIG. 1B is a sectional view of a semiconductor element making up the semiconductor radiation detector according to the first embodiment of the invention.

FIG. 1C is an exploded perspective view showing the semiconductor radiation detector according to the first embodiment of the invention.

FIG. 2 is a block diagram showing a signal processing circuit.

FIG. 3 shows a histogram of the energy resolution due to the semiconductor radiation detector according to the first embodiment of the invention.

FIG. 4 shows a histogram of the energy resolution due to the semiconductor radiation detector as a first comparative example.

FIG. 5 is a schematic diagram showing a cross section, observed under a transmission electron microscope, in the neighborhood of the cathode of the semiconductor crystal of the semiconductor radiation detector according to the first embodiment of the invention.

FIG. 6 is a schematic diagram showing a cross section, observed under a transmission electron microscope, in the neighborhood of the cathode of the semiconductor crystal of the semiconductor radiation detector according to the first comparative example.

FIG. 7 is a diagram showing the energy resolution due to the semiconductor radiation detector according to a second comparative example.

FIG. 8 is a schematic diagram showing the result of analyzing the ratio of the number of atoms between In of the anode and In, Cd and Te of the semiconductor crystal versus the distance from the surface of the anode toward the cathode in the semiconductor radiation detector according to the first embodiment of the invention.

FIG. 9 is a schematic diagram showing the result of analyzing the ratio of the number of atoms between In of the anode and In, Cd and Te of the semiconductor crystal versus the distance from the surface of the anode toward the cathode in the semiconductor radiation detector according to the first comparative example.

FIG. 10 is a diagram showing a general configuration of the positron emission tomography (PET) equipment using the semiconductor radiation detector according to the first embodiment of the invention.

FIG. 11 is a block diagram showing the signal processing circuit of the positron emission tomography (PET) equipment using the semiconductor radiation detector according to a second embodiment of the invention.

FIG. 12 is a diagram showing a general configuration of the single photon emission computed tomography equipment using the semiconductor radiation detector according to the first and second embodiments of the invention.

### DESCRIPTION OF THE INVENTION

Now, the semiconductor radiation detector according to the invention is explained in detail with reference to the drawings as required.

### First Embodiment

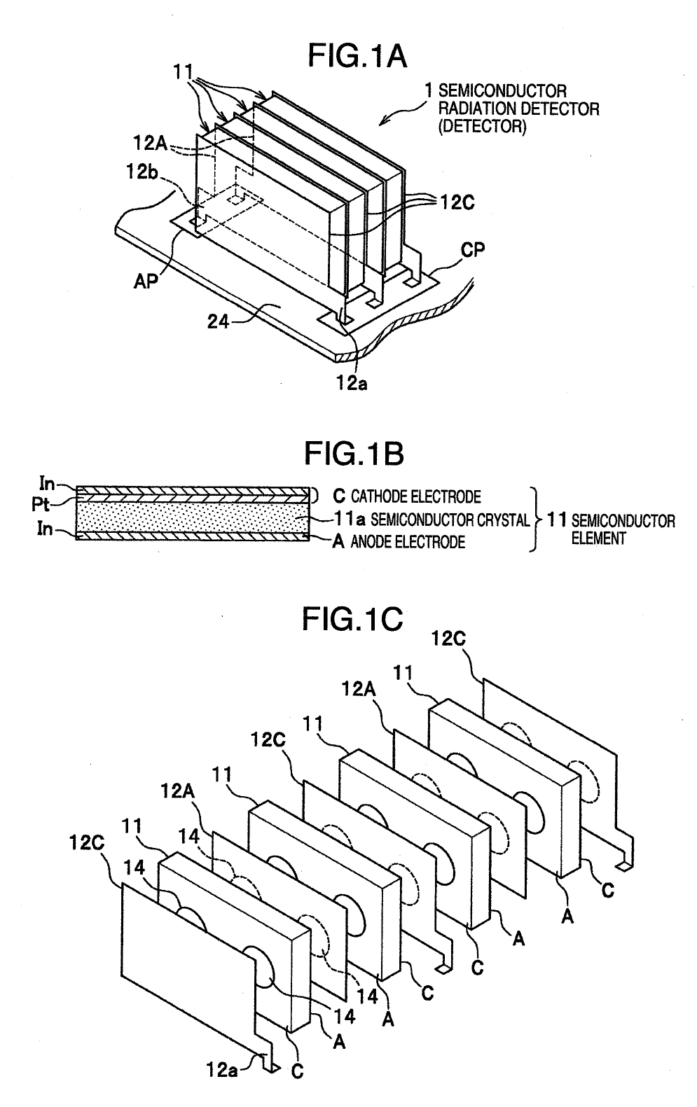

The semiconductor radiation detector (hereinafter referred to simply as the detector) 1 according to this embodiment, as shown in FIG. 1A, is a stack structure including four semiconductor elements 11, and electrode plates 12C, 12A arranged between and at the ends of the semiconductor elements 11.

The semiconductor elements 11, as shown in FIG. 1B, each have a semiconductor crystal 11a formed in the shape of a flat plate, and have a thin-film electrode formed on each entire side surface thereof. Each semiconductor element 11 is formed with a cathode electrode (hereinafter referred to as the cathode) C on one surface thereof and an anode electrode (hereinafter referred to as the anode) A on the other surface thereof.

The semiconductor crystal 11a constitutes an area for generating the charge by interaction with the radiation (γ ray, etc.), and is formed by slicing the single crystal of CdTe, CdZnTe or GaAs. According to this embodiment, each semiconductor crystal 11a is a thin rectangular member about 1 mm thick.

The semiconductor crystal 11a and the cathode C are in ohmic contact with each other, while the semiconductor crystal 11a and the anode A are in Schottky contact with each other.

The cathode C making up one of the electrodes has a stack structure, and according to this embodiment, a first layer deposited on the semiconductor crystal 11a is formed of Pt and a second layer deposited on the first layer is formed of In thereby to constitute a double-layer structure. Alternatively, the first layer may be formed of Au or an alloy with Pt or Au as a main component. Also, the second layer is not limited to In but may be formed of any metal lower in hardness than the metal (Pt or Au) making up the first layer. The second layer may be formed of, for example, an alloy with In as a main component (Mohs scale of hardness: about 1.2 to 2.4).

The metal In of the second layer making up the cathode C is formed on (the outside of) the metal Pt of the first layer by the electroless plating.

As another alternative, still another metal usable as an electrode may be formed on the metal In of the second layer of the cathode C. Similarly, still another metal usable as an electrode may be formed as a second layer on the metal Pt of the first layer, and In may be stacked thereon.

According to this embodiment, the anode A making up the second electrode has a single-layer structure formed of In. The anode A may be either a single-layer structure formed of any one of In, Ti and Al or a double-layer stack structure as a combination of at least two of In, Ti and Al including a first layer.

The fabrication process of the semiconductor element 11 having the cathode C and the anode A described above is explained below.

First, a first surface of the semiconductor crystal 1a is deposited with In to the thickness of about 100 nm by the electron beam evaporation method thereby to form the anode A. After that, the second surface is deposited with Pt to the thickness of about 50 nm by the electroless plating method thereby to form the first layer of the cathode C.

Next, In is deposited to the thickness of about 100 nm on (the outside of) the first layer of the cathode C thereby to form the second layer of In. In the process, the electroless plating of In is carried out using a plating liquid prepared from indium chloride 6 g/L, thiocarbamide 55 g/L and tartaric acid 40 g/L.

As a result, a semiconductor element 11 including the cathode C having the first layer of Pt with the second layer of In stacked thereon and the anode A of In is obtained.

Incidentally, as described above, the first and second layers of the cathode C, both deposited by the electroless plating method, can be formed in a room temperature environment without being exposed to a high temperature unlike in the evaporation method. As a result, In of the anode A formed previously is not affected by heat.

The electrode plates 12C, 12A are thin-plate members formed of at least one of an iron-nickel alloy, an iron-nickel-cobalt alloy, chromium and tantalum. The electrode plates 12C, 12A, as shown in FIGS. 1A and 1C, are each formed with a protruded portion 12a (12b) drooped downward of the semiconductor elements 11 (toward the wiring board 24 shown in FIG. 1A). This protruded portion 12a (12b) functions as a fixing portion for electrically mounting the detector 1 on the wiring board 24. Incidentally, the detector 1 is fixedly mounted using solder or the like not shown.

The detector 1 having the semiconductor elements 11 and the electrode plates 12C, 12A, as shown in FIG. 1C, is so configured that the semiconductor elements 11 are arranged in parallel to each other with the cathodes C facing each other and the anodes A facing each other, so that the electrodes of the same type (cathodes C or the anodes A) are electrically connected to each other through the electrode plates 12C, 12A. Specifically, each electrode plate 12C is arranged between the opposed cathodes C of the adjacent semiconductor elements 11 and mounted on the respective cathodes C by electroconductive adhesives 14. The electrode plates 12A, on the other hand, are each arranged between the opposed anodes A of the adjacent semiconductor elements 11 and mounted on the respective anodes A by the electroconductive adhesives 14. Further, the electrode plate 12C is bonded by the electroconductive adhesive 14 to each cathode C located at each end of the detector 1. In this way, the detector 1 includes the cathodes C and the anodes A arranged alternately with each other and the electrode plates 12C, 12A similarly arranged alternately with each other.

The electroconductive adhesive 14 is formed of, for example, the electroconductive particles of such as metal (silver) dispersed in an insulative resin binder of an organic polymer material. Normally, in the case where the semiconductor elements 11 and the electrode plates 12C, 12A are bonded to each other by the electroconductive adhesive 14, the electroconductive adhesive 14 is hardened by applying a predetermined pressure to the electrode plates 12C, 12A at the ends of the detector 1 from the direction perpendicular to the surfaces of the electrode plates 12C, 12A, followed by the heat treatment at a temperature as high as about 120 to 150 ° C. The pressure applied in the process is, for example, about 9.80665 N in the case where the surface of each semiconductor element 11 is in the shape of a square having the side length of 5 mm.

Then, the detector 1, as shown in FIG. 1A, is arranged on the wiring board 24 by connecting the protruded portions 12a of the cathode C-side electrode plates 12C to the connecting member CP for the cathodes C and the protruded portions 12b of the anode A-side electrode plates 12A to the connecting member AP for the anodes A.

Next, the radiation detection equipment 30 configured of the detector 1 described above is explained.

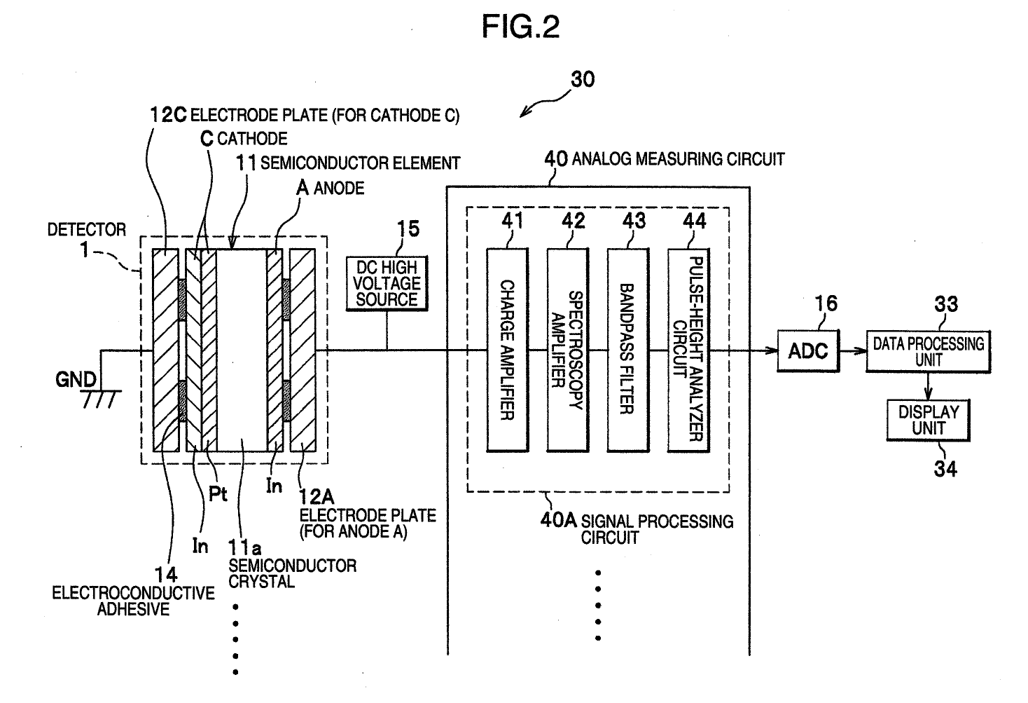

In the detector 1 of the radiation detection equipment 30, as understood from the stack structure simplistically shown in FIG. 2, the electrode plate 12C for the cathode C is grounded, while the electrode plate 12A for the anode A is connected to a signal processing circuit 40A arranged in an analog measuring circuit 40 through a DC high voltage source 15. The DC high voltage source 15 applies a charge collection voltage of 500 to 800 V to the detector 1. In other words, the detector 1 is impressed with a reverse bias voltage (for example, such a reversely applied voltage that the cathode C is at the ground potential and the anode A at +500 V, i.e. the anode A is higher than the cathode C by 500 V).

The analog measuring circuit 40 has the signal processing circuit 40A connected to the detector 1 for processing the radiation detection signal (γ-ray detection signal) output from the detector 1. The signal processing circuit 40A is arranged in association with each one detector 1. This signal processing circuit 40A, intended to determine the pulse-height value of the γ ray based on the γ-ray detection signal, includes a charge amplifier (preamplifier) 41, a spectroscopy amplifier (linear amplifier) 42, a bandpass filter 43 and a pulse-height analyzer circuit 44. The charge amplifier 41, the spectroscopy amplifier 42, the bandpass filter 43 and the pulse-height analyzer circuit 44 are connected in that order.

The γ-ray detection signal output from the detector 1 is amplified by the charge amplifier 41 and the spectroscopy amplifier 42. The γ-ray detection signal thus amplified is input to the pulse-height analyzer circuit 44 through the bandpass filter 43. The pulse-height analyzer circuit 44 holds the maximum value of the detection signal, i.e. the pulse height value of the γ-ray detection signal proportional to the energy of the γ ray detected.

The signal output from the pulse-height analyzer circuit 44 of the signal processing circuit 40A is an analog pulse-height value signal, which is converted into a digital signal by an ADC (analog-to-digital converter) 16. The ADC 16 outputs the converted digital signal of the pulse height value to the data processing unit 33. The data processing unit 33 counts the pulse-height value signal for each input pulse height value. The data processing unit 33 prepares the information on the count (γ-ray count) of the pulse height value (γ-ray energy), and stores it in a storage unit (not shown). The information prepared by the data processing unit 33 is displayed on the display unit 34.

The operation of the radiation detection equipment 30 is explained with reference to the drawings as required. Upon entrance of the γ ray into the semiconductor element 11 of the detector 1, the semiconductor element 11 interacts with the γ ray thereby to produce pairs of holes and electrons in the number proportional to the energy held by the γ ray. A voltage of 500 to 800 V from the DC high voltage source 15 is applied between each electrode plate 12A for the anode A and the corresponding electrode plate 15 for the cathode C. Thus, the holes move toward the electrode plate 12C for the cathode C, and the electrons move toward the electrode plate 12A for the anode A. Then, the detector 1 outputs a γ-ray detection signal indicating the magnitude of the energy of the γ ray that has entered the semiconductor element 11 in accordance with the amount of the electrons collected by the electrode plate 12A, i.e. the magnitude of the charge.

The γ-ray detection signal output from the detector 1 is amplified by the charge amplifier 41 and the spectroscopy amplifier 42 and, after passing through the bandpass filter 43, input to the pulse-height analyzer circuit 44. The pulse-height analyzer circuit 44 analyzes the γ-ray detection signal passed through the bandpass filter 43 thereby to generate an analog pulse-height value signal. This analog pulse-height value signal is converted into a digital pulse-height value signal by the ADC 16 and output to the data processing unit 33.

After that, the data processing unit 33, based on the input pulse-height value signal, calculates the pulse height value indicating the magnitude of the energy of the γ ray received by the detector 1, and generates the information (for example, a γ-ray spectrum graph) on the count (γ-ray count) for the pulse-height value (γ-ray energy). The information (for example, the γ-ray spectrum graph) generated by the data processing unit 33 is displayed on the display unit 34.

The present inventors have constructed the radiation detection equipment 30 using 1024 detectors 1 fabricated by stacking the semiconductor elements 11 with a square surface having each side length of 5 mm and measured the characteristics thereof using the γ ray of 662 keV of cesium (¹³⁷Cs) having a source strength of 2500 kBq. In the process, 1024 γ-ray spectra of 662 keV in energy can be obtained based on the pulse-height value signal from the 1024 detectors. The full width at half maximum of the γ-ray spectra thus obtained standardized by 662 keV is calculated as an energy resolution, and by preparing a histogram, the characteristics were studied.

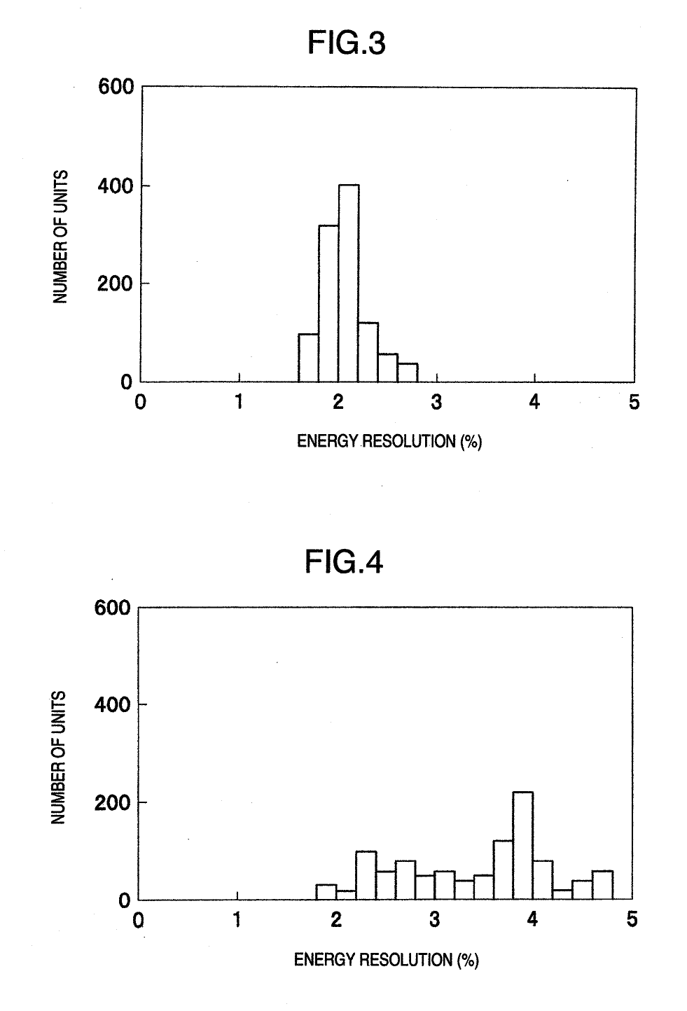

The result is shown in FIG. 3. From the result shown in FIG. 3, the average value of the energy resolution was determined. Then, the energy resolution as high as 2.1% could be obtained.

On the other hand, the detector described below was fabricated as a first comparative example, and the characteristics thereof were measured similarly with the radiation detection equipment 30 described above.

The detector according to the first comparative example has the electrode of the cathode C is formed of a single layer of Pt. Specifically, the detector according to the first comparative example, unlike the detector 1 according to this embodiment, was fabricated by pressing the electrode plate 12C directly against the cathode C of the single Pt layer through the electroconductive adhesive 14 without forming the second layer of In in the cathode C.

Also in this case, the radiation detection equipment 30 is configured of 1024 detectors according to the first comparative example each formed by stacking the semiconductor elements, not shown, with a square surface having each side length of 5 mm, and the characteristics are measured using the γ ray of 662 keV of cesium 137 (¹³⁷Cs) having the source strength of 2500 kBq. The full width at half maximum of the γ-ray spectrum as standardized with 662 keV was calculated as the energy resolution, and the characteristics studied as a histogram.

The result is shown in FIG. 4. From the result shown in FIG. 4, the average value of the energy resolution was determined as 3.7%. Thus, the energy resolution is remarkably low as compared with the detector 1 according to this embodiment, i.e. the detector 1 formed with In stacked as a second layer of the cathode C.

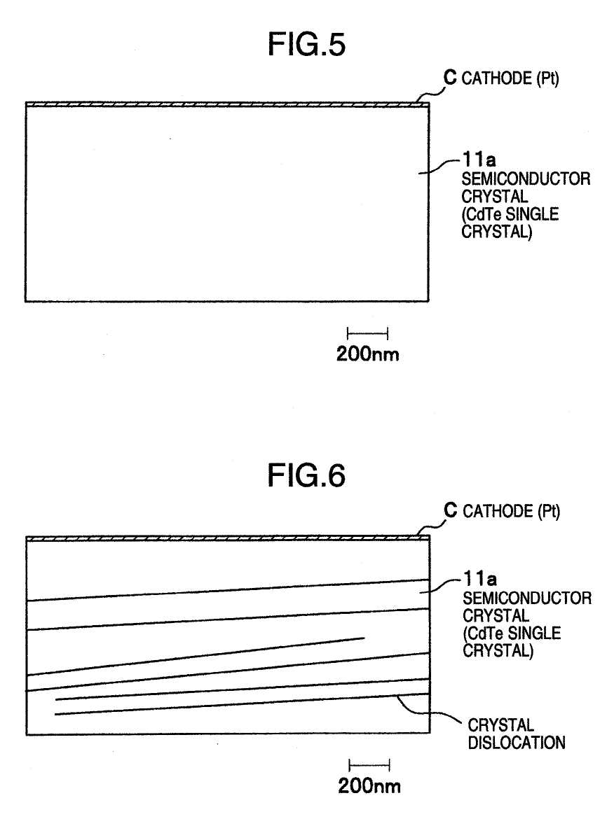

In order to trace the cause of the reduced energy resolution, the cross section in the neighborhood of the cathode C of the semiconductor crystal 11a was observed under the transmission electron microscope for the two cases in which In is stacked and not stacked as the second layer of the cathode C. The result is briefly shown in FIGS. 5 and 6, respectively.

The observation of the cross section of the semiconductor crystal 11a (CdTe single crystal) in the neighborhood of the cathode C (Pt) indicates that no crystal dislocation occurs, as shown in FIG. 5, in the detector 1 according to this embodiment with In stacked as the second layer.

In the detector according to the first comparative example with no In formed, in contrast, as shown in FIG. 6, a multiplicity of crystal dislocations (indicated by lines running diagonally rightward and leftward) are observed.

This difference is probably derived from the fact that In having the Mohs hardness of 1.2 is milder than Pt of the cathode C having the Mohs hardness of 4.3. In the detector 1 according to this embodiment using In as the cathode C, the pressure used for fabrication is suitably relaxed by In. In the detector 1, the semiconductor crystal 11a develops no crystal dislocation, and therefore, the charge generated by absorbing the incident γ ray is probably collected efficiently into the electrodes, resulting in a high energy resolution.

In the detector according to the first comparative example, on the other hand, the forming pressure directly acts on the semiconductor crystal 11a through Pt, with the probable result that a multiplicity of crystal dislocations occur in the semiconductor crystal 11a in the neighborhood of the cathode C.

Once the crystal dislocations occur in this way, the charge generated by the absorption of the incident γ ray is collected less efficiently into the electrode, thereby probably reducing the energy resolution as shown by the result of observation described above.

Also, as a second comparative example, a detector described below was fabricated, and the characteristics were measured similarly using the radiation detection equipment 30 described above.

The detector according to the second comparative example is stacked with In as a second layer of the cathode C not by the electroless plating method but by the electron beam evaporation method. While In was formed by the electron beam evaporation method, the temperature of the cathode C and the semiconductor crystal 11a was maintained at about 220° C. As compared with the room temperature environment in which In is formed by the electroless plating method, therefore, the temperature to which the detector is exposed has a great difference.

Also in this case, the radiation detection equipment 30 was constructed using 1024 detectors according to the second comparative example each fabricated by stacking the semiconductor elements 11, not shown, with a square surface having each side length of 5 mm, and the characteristics thereof measured using the γ ray of 662 keV of cesium 137 (¹³⁷Cs) having a source strength of 2500 kBq. In the process, the full width at half maximum of the γ-ray spectra, as standardized by 662 keV, was calculated as an energy resolution, and by creating a histogram, the characteristics were studied.

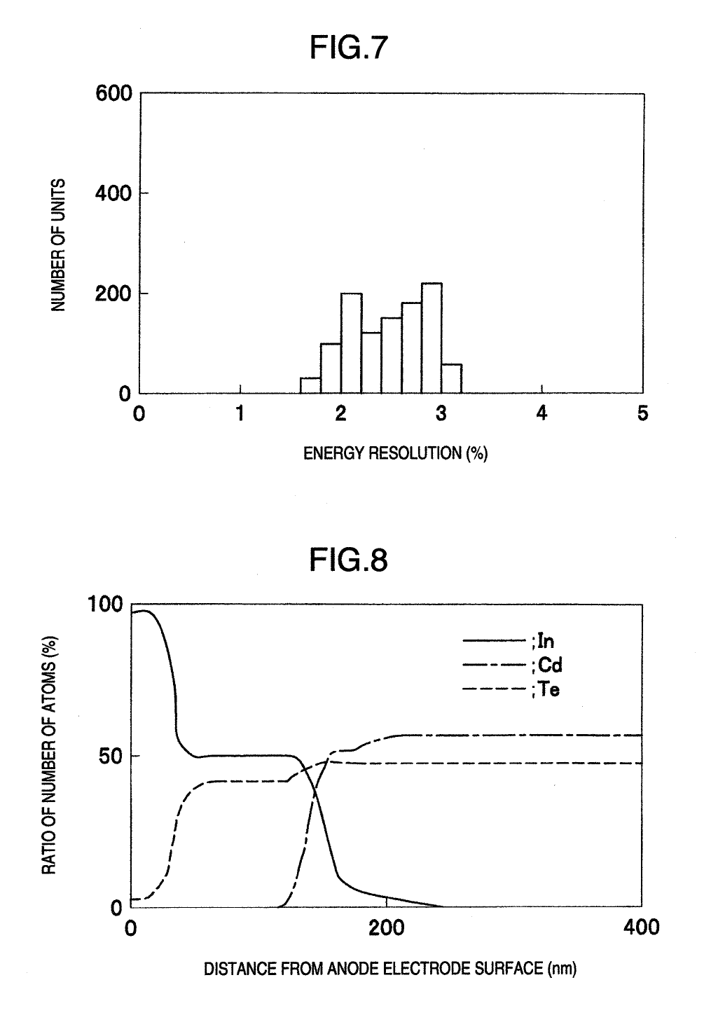

The result is shown in FIG. 7. From the result shown in FIG. 7, the average value of the energy resolution was determined at 2.5%, indicating the reduction in energy resolution as compared with the detector 1 according to this embodiment in which In is formed by the electroless plating method.

In order to trace the cause of this reduced energy resolution, the degree of the effect on the anode A was verified in the case where In of the cathode C is formed by the electroless plating method and in the case where it is formed by the electron beam evaporation method.

As a method of verification, the ratio of the number of atoms between In of the anode A and In, Cd and Te in the semiconductor crystal 11a (CdTe single crystal) was analyzed with respect to the distance from the surface of the anode A toward the cathode C. The SIMS (secondary ion mass spectroscopy) was employed for analysis.

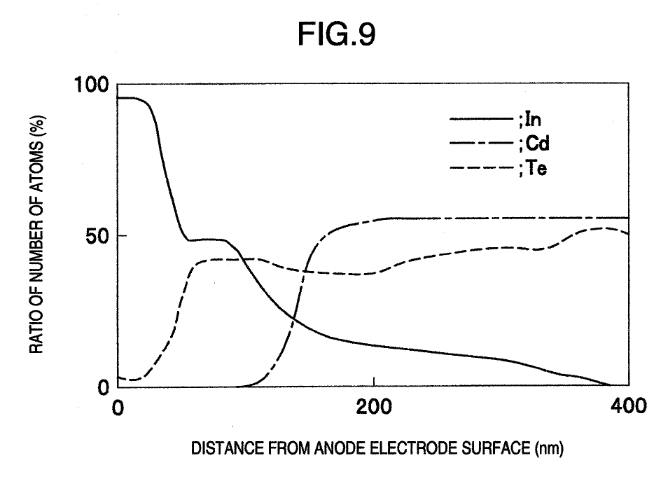

The result is shown in FIGS. 8 and 9. FIG. 8 shows the case in which In of the cathode C is formed by the electroless plating method, and FIG. 9 the case in which In of the cathode C is formed by the electron beam evaporation method.

It is apparent from these diagrams that in the case where In is formed by the electron beam evaporation method as shown in FIG. 9, as compared with the case in which it is formed by the electroless plating method as shown in FIG. 8, In of the anode A is diffused as deep as about 400 nm into the single crystal of CdTe of the semiconductor crystal 11a.

This is by reason of the fact that the melting point of In is 157° C., and in forming In of the cathode C by the electron beam evaporation method, the temperature of the semiconductor crystal 11a increases to a higher level of 220° C., with the probable result that In forming the anode A has diffused into the semiconductor crystal 11a (CdTe single crystal). With the diffusion of In into the semiconductor crystal 11a (CdTe single crystal) in this way, a crystal defect occurs, and the charge generated by the absorption of the incident γ ray is collected into the electrode less efficiently, probably resulting in the reduction in the energy resolution.

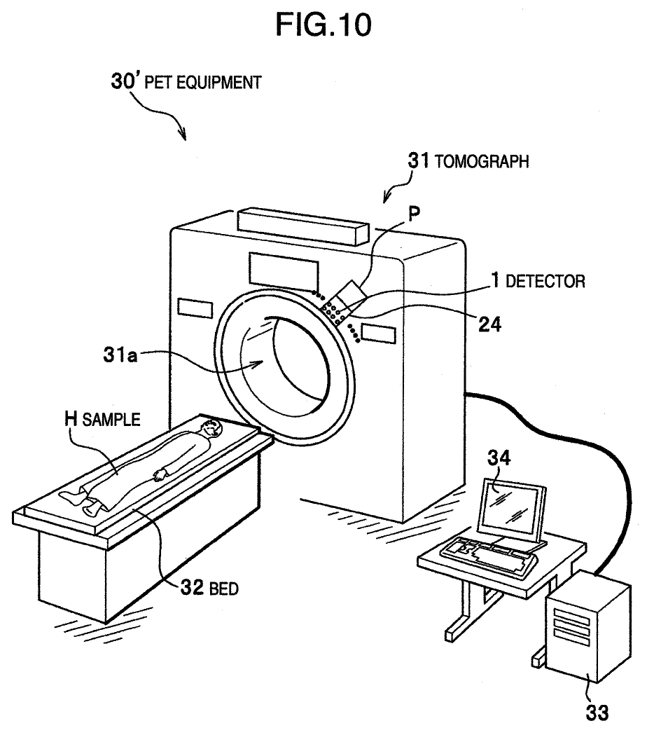

The detector 1 according to this embodiment described above, as shown in FIG. 10, can be used for a PET equipment 30′ as a radiation detection equipment. The PET equipment 30′ includes a tomograph 31 having a central solid-cylindrical measurement space (measurement area) 31a, a bed 32 movable longitudinally while supporting a sample (patient to be diagnosed) H, a data processing unit (image information generating unit such as a computer) 33 and a display unit 34 as main component elements.

In the tomograph 31, a printed board P with a multiplicity of the detectors 1 mounted on the wiring board 24 (FIG. 1A) is arranged in such a manner as to surround the measurement space 31a.

This PET equipment 30′, in addition to a DC high voltage source 15 used for the radiation detection equipment 30, an analog measuring circuit 40 and an ADC 16, includes a data processing circuit (digital ASIC) not shown. Thus, a packet having the pulse-height value, time and the element ID of the detector 1 is produced and input to the data processing unit 33.

At the time of inspection, a high DC voltage is applied between the anode A and the cathode C of each detector 1 from the DC high voltage source 15, and the γ ray emitted due to the radioactive pharmaceutical from the body of the sample H is detected by the detector 1. Specifically, at the time of extinction of the positron emitted from the radioactive pharmaceutical for PET, a pair of γ rays is emitted in the opposite directions of about 180° and detected by different detectors 1. The γ-ray detection signal thus detected is input to the signal processing circuit 40A (FIG. 2) of the corresponding analog measuring circuit 40, and further input from the analog measuring circuit 40 to the ADC 16 thereby to execute the signal processing as described above. Then, the positional information of the detector 1 that has detected the γ ray and the γ-ray detection time information are input to the data processing unit 33 by a digital ASIC (not shown). The data processing unit 33 counts a pair of γ rays generated by the extinction of one positron as one, and specifies the positions of the two detectors 1 that have detected the particular pair of the γ rays, based on the positional information thereof. Also, the data processing unit 33, using the count value and the positional information of the detector 1 obtained by simultaneous measurement, prepares the tomography image information (image information) of the sample H at the integrated position of the radioactive pharmaceutical, i.e. at the position of a malignant tumor. This tomography information is displayed on the display unit 34.

With this PET equipment 30′, the energy resolution and the positional resolution are improved in accuracy.

The advantages of this embodiment are explained below.

(1) The cathode C is a stack structure having the first layer of Pt and the second layer formed of In milder (lower in hardness) than Pt of the first layer. In the assembly process of the detector 1, therefore, the metal In of the second layer functions as a buffer material against the first layer formed of Pt harder than In, so that the pressure for bonding the electrode plates 12C, 12A through the electroconductive adhesive 14 can be suitably relaxed. As a result, no crystal dislocation occurs in the semiconductor crystal 11a, and the deterioration of the detection characteristic of the detector 1 can be suitably prevented.

(2) The metal In contained in the second layer of the cathode C is formed by the electroless plating method, and therefore, can be formed without exposing the semiconductor crystal 11a to a high temperature. Even in the case where In low in melting point is formed as an electrode on the anode A of the semiconductor crystal 11a in the previous process, therefore, neither In of the anode A nor the semiconductor crystal 11a in contact therewith is deteriorated by heat. Thus, the deterioration of the detection characteristic of the detector 1 is suitably prevented.

(3) With a stack structure using In, Ti and Al and a combination of at least two of In, Ti and Al as the first layer of the anode A, the electrode of the anode A of the semiconductor crystal 11a can be suitably rendered to function. Especially, with the anode A as a single layer of In or a stack structure using In as a first layer, the metal In can have dual function as an electrode and as a buffer material for alleviating the pressure of bonding the electrode plate. As a result, the deterioration of the detection characteristic can be suitably prevented.

(4) In the PET equipment 30′ using the detector 1 according to this embodiment, the deterioration of the detection characteristic of the detector 1 is suitably prevented, thereby improving the accuracy of the energy resolution and the positional resolution

### Second Embodiment

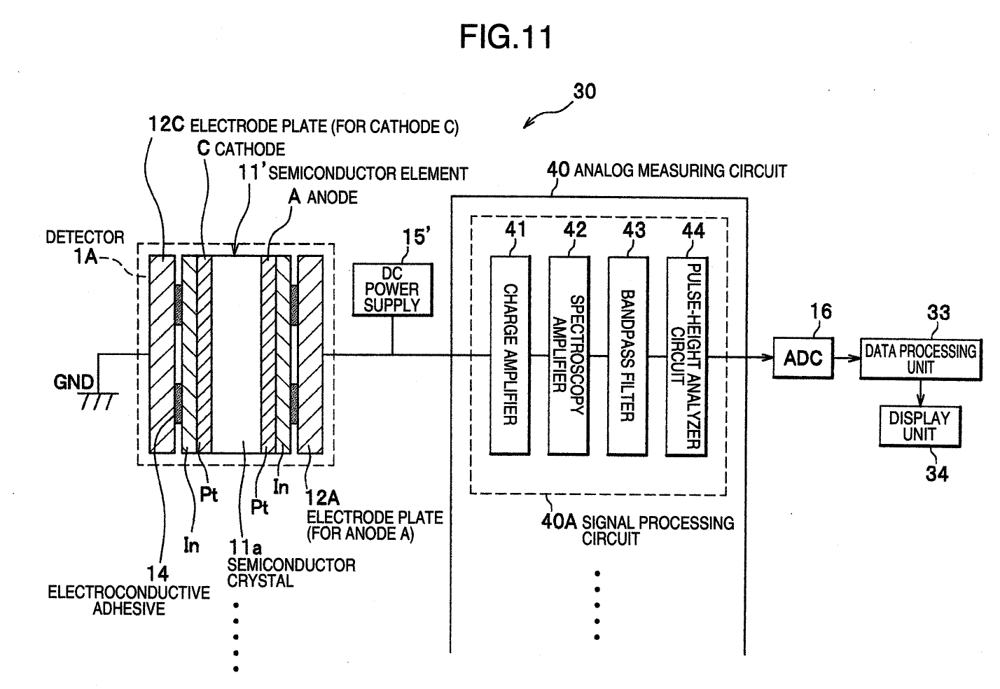

A detector according to a second embodiment of the invention is explained. The detector 1A according to this embodiment, as shown partially in FIG. 11, is different from the first embodiment in that both the electrodes of the cathode C and the anode A are in a double stack structure, each with the first layer of Pt and the second layer of In. Incidentally, the semiconductor crystal 11a is in the shape of a tabular rectangle similar to the first embodiment.

Now, the fabrication process of the semiconductor element 11′ having the cathode C and the anode A of this structure is explained.

First, Pt is deposited to the thickness of about 50 nm by the electroless plating method on the two surfaces of the semiconductor crystal 11a thereby to form the first layer of the cathode C and the anode A.

After that, In is deposited to the thickness of about 100 nm by the electroless plating method on the first layer of the cathode C and the anode A thus formed thereby to form the second layer of the cathode C and the anode A, respectively.

The electroless plating of In is conducted using a plating liquid prepared from indium chloride 6 g/L, thiocarbamide 55 g/L and tartaric acid 40 g/L.

As a result, the cathode C and the anode A each with the first layer of Pt and the second layer of In are formed on both surfaces of the semiconductor crystal 11a.

Incidentally, as described above, the first and second layers are both formed by the electroless plating method in a room temperature environment, and therefore, not exposed to a high temperature unlike in the evaporation method.

In the detector 1A having the semiconductor elements 11 and the electrode plates 12C, 12A as described above, like in the aforementioned embodiment, the semiconductor elements 11′ are arranged in parallel to each other with the cathodes C facing each other and the anodes C facing each other, and the same type of electrodes (cathodes C or anodes A) are electrically connected to each other with an electroconductive adhesive 14 through the electrode plates 12C, 12A (FIG. 1C). The pressure under which the electroconductive adhesive 14 is hardened is considered about 9.80665 N in the case where each semiconductor element 11′ has a 5-mm side square surface.

In the radiation detection equipment 30 configured of this detector 1A, as shown in FIG. 11, the electrode plate 12C of the cathode C is grounded and the electrode plate 12A of the anode A is connected to the signal processing circuit 40A in the analog measuring circuit 40 through a DC power supply 15′. The DC power supply 15 applies a voltage of 60 to 100 V for charge collection to the detector 1A.

Incidentally, the analog measuring circuit 40, the ADC 16, the data processing unit 33 and the display unit 34 are identical with those in the aforementioned embodiment and therefore not described in detail.

The present inventors have constructed a radiation detection equipment 30 using 1024 detectors 1A each fabricated by stacking semiconductor elements 11′ having a 5-mm side square surface, and the characteristics thereof measured using the γ ray of 662 keV of cesium 137 (¹³⁷Cs) having a source strength of 2500 kBq. In this case, based on the pulse-height value signal obtained from the 1024 detectors 1A, 1024 γ-ray spectra having the energy of 662 keV can be obtained. Then, the full width of half maximum of the γ-ray spectra as standardized by 662 keV is calculated as an energy resolution, resulting in the average value of about 6%.

On the other hand, a detector, not shown, was formed with the cathode C and the anode A in a single layer of Pt as another comparative example, and using this detector with the radiation detection equipment 30 described above, the characteristics were similarly measured. Specifically, the detector according to this comparative example was fabricated by pressing the electrode plates 12C, 12A directly against the cathode C and the anode A in a single layer of Pt without forming the second layer of In unlike the detector 1A according to this embodiment.

Also in this case, the radiation detection equipment 30 was constructed using 1024 detectors according to this comparative example each fabricated by stacking the semiconductor elements, not shown, each having a square surface with 5-mm side length, and the characteristics thereof measured using the γ ray of 662 keV of cesium 137 (¹³⁷Cs) having the source strength of 2500 kBq. Then, the full width of half maximum of the γ-ray spectra as standardized by 662 keV was calculated as an energy resolution, resulting in the average value of about 8%. Thus, the energy resolution is reduced as compared with the aforementioned case in which In is formed as the second layer.

This is considered to indicate that the second layer of In of the detector 1A functions as a buffer material for relaxing the pressure of fabrication, and the crystal dislocation is suitably prevented from occurring in the semiconductor crystal 11a. As a result, the charge generated by the absorption of the incident γ ray is collected by the electrodes smoothly, and a detector 1A having a predetermined energy resolution is obtained.

Incidentally, the first layer of the cathode C and the anode A is not limited to Pt but may be formed of Au. Also, the second layer is not limited to In but may be formed of any metal lower in hardness than the metal (Pt, Au) used for the first layer. The second layer can be formed of, for example, an alloy (Mohs scale of hardness: about 1.2 to 2.4) with In as a main component.

The detectors 1, 1A according to the first and second embodiments described above are not limited to the PET equipment 30′, but applicable also with a gamma camera or a single photon emission computed tomography equipment (SPECT equipment) with equal effect.

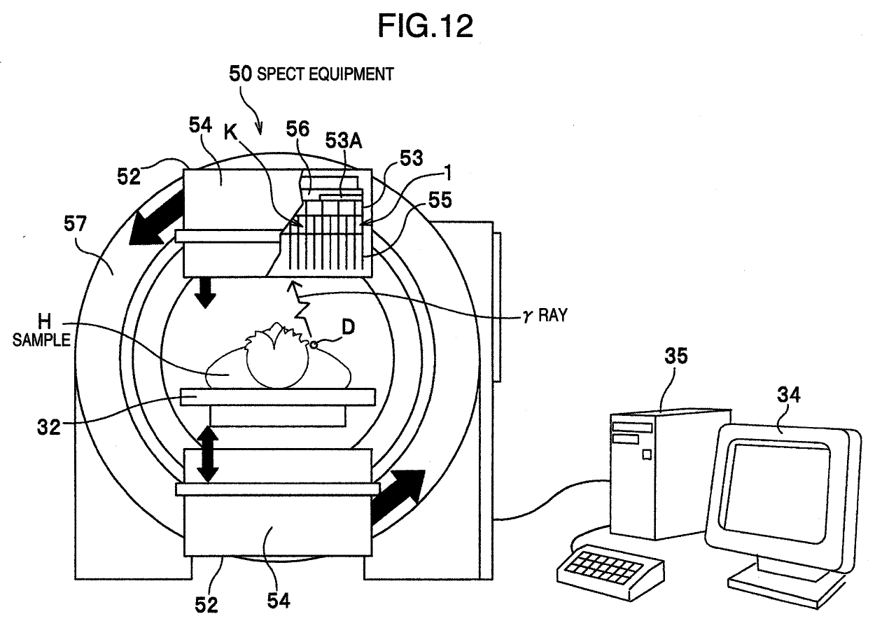

This SPECT equipment 50 is explained with reference to FIG. 12. The SPECT equipment 50 includes a pair of radiation detection blocks 52, 52, a rotary support table (rotary unit) 57, a data processing unit 35 and a display unit 34.

The radiation detection blocks 52, 52 are arranged 180° displaced along the peripheral direction on the rotary support table 57. Specifically, the unit support members 56 (only one is shown) of the radiation detection blocks 52, 52 are mounted on the rotary support table 57 at peripheral intervals of 180°. A plurality of detector units 53A each including a coupling board 53 are mounted removably on the unit support members 56. The plurality of the detectors 1 (or 1A) are arranged in multiple stages within an area K defined by a collimator 55 (not shown). The collimator 55 is formed of a radiation shield material (for example, lead, tungsten, etc.) and forms a multiplicity of radiation paths for passing the radiation (for example, γ ray). All the coupling boards 53 and the collimators 55 are arranged in a photo-masking/electromagnetic shield 54 on the rotary support table 57. The photo-masking/electromagnetic shield 54 protects the detectors 1 from the effect of the electromagnetic wave other than γ ray.

In the SPECT equipment 50, a bed 32 having mounted thereon a sample H dosed with a radioactive pharmaceutical is moved so that the sample H is moved between a pair of the radiation detection blocks 52. With the rotation of the rotary support table 57, each radiation detection block 52 revolves around the sample H. The γ ray emitted from the integrated portion (such as a diseased part) in the sample H with the radioactive pharmaceutical integrated enters the corresponding detector 1 through the radiation path of the collimator 55. The detector 1 outputs a γ-ray detection signal, which is processed in the analog measuring circuit 40 (FIG. 3), and then, the information on the count (γ-ray count) for the pulse-height value (γ-ray energy) is produced from the data processing unit 35. This information is displayed on the display unit 34.

In the SPECT equipment 50 using this detector 1 (1A), the deterioration of the detection characteristic of each detector 1 (1A) is suitably prevented, and therefore, the energy resolution and the positional resolution are improved in accuracy.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor radiation detector formed of the semiconductor crystal of at least selected one of CdTe, CdZnTe, GaAs and TlBr held by the electrodes of the cathode and the anode,
wherein at least a first one of the electrodes has a stack structure including a plurality of metals; and
wherein a first layer is formed of Pt, and a second layer is formed of a metal lower in hardness than Pt of the first layer.

2. A semiconductor radiation detector formed of the semiconductor crystal of at least selected one of CdTe, CdZnTe, GaAs and TlBr held by the electrodes of the cathode and the anode,
wherein at least a first one of the electrodes has a stack structure including a plurality of metals; and
wherein a first layer is formed of Au, and a second layer is formed of a metal lower in hardness than Au of the first layer.

3. The semiconductor radiation detector according to claim 1, wherein the second layer is formed of In.

4. The semiconductor radiation detector according to claim 2, wherein the second layer is formed of In.

5. The semiconductor radiation detector according to claim 1, wherein a first one of the electrodes further includes a metal stacked on the second layer.

6. The semiconductor radiation detector according to claim 2, wherein the first one of the electrodes further includes a metal stacked on the second layer.

7. The semiconductor radiation detector according to claim 3, wherein In of the second layer is formed by the electroless plating method.

8. The semiconductor radiation detector according to claim 4, wherein In of the second layer is formed by the electroless plating method.

9. The semiconductor radiation detector according to claim 1, wherein the second one of electrodes different from the first one of the electrodes is formed of selected one of In, Ti and Al.

10. The semiconductor radiation detector according to claim 2, wherein the second one of the electrodes different from the first one of the electrodes is formed of selected one of In, Ti and Al.

11. The semiconductor radiation detector according to claim 1, wherein the second one of the electrodes different from the first one of the electrodes is a stack structure including a combination of at least two of In, Ti and Al with one of In, Ti and Al as a first layer.

12. The semiconductor radiation detector according to claim 2, wherein the second one of the electrodes different from the first one of the electrodes is a stack structure including a combination of at least two of In, Ti and Al with one of In, Ti and Al as a first layer.

13. A radiation detection equipment using the semiconductor radiation detector according to claim 1, comprising:
a plurality of printed boards each including a wiring board having a plurality of the semiconductor radiation detectors mounted thereon and surrounding a measurement area with a bed supporting a sample inserted therein, the printed boards being arranged around the measurement area; and
an image information generating device for generating an image using the information obtained based on the radiation detection signal output from the plurality of the semiconductor radiation detectors.

14. A radiation detection equipment using the semiconductor radiation detector according to claim 2, comprising:
a plurality of printed boards each including a wiring board having a plurality of the semiconductor radiation detectors mounted thereon and surrounding a measurement area with a bed supporting a sample inserted therein, the printed boards being arranged around the measurement area; and
an image information generating device for generating an image using the information obtained based on the radiation detection signal output from the plurality of the semiconductor radiation detectors.
